(19) United States
(12) Patent Application Publication
(10) Pub. No.: US 2003/0059535 A1
(43) Pub. Date: Mar. 27, 2003

(54) Cycling deposition of low temperature films in a cold wall single wafer process chamber

(76) Inventors: Lee Luo, Fremont, CA (US); Sang Hoon Ahn, Santa Clara, CA (US); Aihua Chen, San Jose, CA (US); Ramaseshan Suryanarayanan Iyer, Santa Clara, CA (US); Shulin Wang, Campbell, CA (US); Randhir P. Singh Thakur, San Jose, CA (US)

Correspondence Address: APPLIED MATERIALS, INC., 2881 SCOTT BLVD. M/S 2061, SANTA CLARA, CA, 95050, US

(21) Appl. No.: 09/964,075

(22) Filed: Sep. 25, 2001

(51) Int. Cl. B32B 9/00; C23C 16/00

(52) U.S. Cl. 427/255.28; 428/446; 428/698; 427/569

(57) ABSTRACT

A method for film deposition that includes, flowing a first reactive gas over a top surface of a wafer in a cold wall single wafer process chamber to form a first half-layer of the film on the wafer, stopping the flow of the first reactive gas, removing residual first reactive gas from the cold wall single wafer process chamber, flowing a second reactive gas over the first half-layer to form a second half-layer of the film where deposition of the second half-layer is non self-limiting, controlling a thickness of the second half-layer by regulating process parameters within the cold wall single wafer process chamber, stopping the flow of the second reactive gas; and removing residual second reactive gas from the cold wall single wafer process chamber.

### FIELD OF THE INVENTION

This invention in general relates to film deposition onto a substrate and in particular to the field of applying a thin film onto a wafer surface by depositing alternating half-layers.

### BACKGROUND OF THE INVENTION

There is considerable interest in ultra-thin dielectric films for metal-oxide-semiconductor field-effect transistor (MOSFET), dynamic random access memory (DRAM), flash memory, and so on. For higher densities of large scale integration, thinner gate-oxide and capacitor dielectric films are necessary.

As the drive for advanced technology lowers process temperature and critical device feature size, most single wafer CVD chambers, as well as all furnaces, have an inherent pattern loading effect when coating a wafer with a film. Within each wafer, pattern loading provides a film thickness on a dense device pattern that is thinner than on a less dense device pattern. The pattern loading on a wafer is defined as the difference between the maximum thickness on a least dense pattern area and the minimum thickness on a most dense pattern area, divided by the maximum thickness on the least dense pattern area. The pattern loading effect in single wafer chambers results mainly from the fast deposition and becomes a critical issue for a pattern width smaller than 0.15 um and an aspect ratio larger than 1.

Recently, techniques have been developed for employing atomic-layer deposition (ALD) within a furnace for conformal and pattern loading-free silicon nitride films, which have high dielectric strength and a smooth surface finish. With these processes, semiconductor devices have deposited within a furnace a very thin ALD silicon nitride layer on top of a SiO₂ surface such as gate and spacer structures. For MOS capacitor fabrication, an ALD silicon nitride (SiN) layer has been deposited by atomic layer control of growth using sequential surface chemical reactions. The ALD has been accomplished within the furnace by separating the chemical reactions that deposit SiN into two half-reactions that are alternately applied to a surface. The first half reaction may supply a silicon precursor such as SiH₂Cl₂, SiCl₄ or Si₂Cl₆ and the second half reaction supply a nitrogen precursor (to form the nitride) such as NH₃ or N₂H₄. In one case, the silicon precursor exposure occurs at 375° C. followed by the nitrogen precursor exposure at 550° C. This sequence of each precursor exposure is cyclically repeated five times, leading to a silicon nitride physical thickness of approximately 0.4 nm. Temperatures below 400° C. are required to provide control of the film thickness, which is to maintain the coating from the silicon precursor flow step as self-limiting. Self-limiting coatings grow two dimensionally and will stop as soon as the previous nitrogen precursor-treated layer is covered, i.e. vertical growth does not occur beyond what is provided to cover the surface. As a result, self-limiting coating thicknesses are a monomolecular layer.

The nitrogen precursor flow step is self-limiting with nitrogen surface incorporation at temperatures up to approximately 650° C. As a result, an overall deposition rate depends on the Si precursor flow step and remains constant at process temperatures in the range of approximately 250-400° C. but rapidly increases above 400° C. The processes described above produce by-products that remain in the SiN film. These by-products are H and Cl which are at such high concentrations that if left in the deposited film will act detrimentally on the wafer devices.

### SUMMARY OF THE INVENTION

A method to apply a thin layer of a film onto a substrate is disclosed. The methods describe a process that applies the film within a cold wall single wafer process chamber. The method applies the film through a series of cycles where each cycle includes the separate and alternating deposition of two half-layers of disassociated chemicals that are adsorbed on onto the surface of the substrate. The half-layers react with each other to connect chemically and where the half layers are provided by alternating flows of reactive gasses. In one embodiment, high process temperatures can deposit at least one half-layer in a manner that is non self-limiting for cyclic layer deposition (CLD) and the layer deposited can be more than a single molecule thick. As a result of the higher process temperatures, control of the non self-limiting half-layer thickness can be accomplished by varying other process parameters such as, for example, wafer exposure time, flow rate of reactive gasses, pressure within the cold wall single wafer process chamber, etc. In one embodiment, the film deposited can be one of, or a combination of, silicon nitride (SiN), silicon dioxide (SiO₂), or silicon oxynitride (SiON) film, however the deposited films are not limited to these listed.

In an alternate embodiment, an atomic layer deposition (ALD) is used in the cold wall single wafer process chamber in which the deposition of both half-layers are self limiting. The ALD process can be used to deposit a film that can be one of, or a combination of, silicon nitride (SiN), silicon dioxide (SiO₂), or silicon oxynitride (SiON).

In another alternate embodiment, a mixed layer deposition (MLD) process can be used where the CLD or ALD process can be used in combination with a chemical vapor deposition process (CVD). By mixing CLD or ALD method with the CVD method, based on overall film acceptance criteria, a degree of the advantages of each method can be gained while accepting a degree of the limitations.

### BRIEF DESCRIPTION OF THE DRAWINGS

FIG. 1A is an illustration of an ammonia flow over a silicon surface.

FIG. 1B is an illustration of a nitrided Si surface.

FIG. 1C is an illustration of silicon added to the nitrided surface.

FIG. 1D is an illustration of a non self-limiting condition for HCD.

FIG. 1E is an illustration of a next layer of nitridation.

FIG. 2 is an illustration of a cold wall single wafer process chamber.

FIG. 3 is a flow chart of film deposition in the cold wall single wafer process chamber.

FIG. 4 is an illustration of a barrier seed layer.

FIG. 5A is an illustration of a CLD and a CVD layers in a device dense area.

FIG. 5B is an illustration of the CLD and CVD layers in a device isolated area.

FIG. 5C is an illustration of alternate CLD and CVD layers in a device dense area.

FIG. 5D is an illustration of alternate CLD and CVD layers in a device isolated area.

FIG. 5E is an illustration of a CVD layer in the device dense area.

FIG. 5F is an illustration of the CVD layer in the device isolated area.

FIG. 6A is an illustration of a chemical etch of a CVD deposited portion of a MLD process.

FIG. 6B is an illustration of an etch stop at a CLD deposited portion of the MLD process.

FIG. 7A illustrates one embodiment of a client connected to a server through an ISP provider.

FIG. 7B illustrates one embodiment of a machine such as a computer.

### DETAILED DESCRIPTION OF THE INVENTION

The present invention is a method to deposit a high quality film onto a substrate within a cold wall single wafer process chamber. The films deposited may be, such as, for example, GaAs, InP, Al₂O₃, AlN or silicon-based. The Si-based films may be, for example, silicon nitride (SiN, chemically represented as Si₃N₄), silicon dioxide (SiO₂), or silicon oxynitride (SiON, chemically represented generically as SiOₓN_{y}). The cold wall single wafer process chamber (process chamber) refers to a “cold wall” where the chamber wall of the process chamber is at a lower temperature than the temperature of the chemical reactions going on within the process chamber. Advantages for using the cold wall single wafer chamber include the fact that little or no film deposition occurs on the process chamber walls, easier and faster cleaning is possible, all of which reduces preventive maintenance downtimes. Further benefits can include low metal contamination from the reactor (process chamber) walls leading to higher yield for devices, lower power requirements than from furnaces, and independent controls of the chamber wall temperature. In addition, chamber walls can be coated with different coatings, and along with the chamber wall temperature, can be useful for different chemistries for film processing.

The present invention is a method that applies the film where film deposition is separated into two half-layers each deposited by a half reaction, i.e., half of the reaction chemistry necessary for total film deposition. The half reactions are applied in an alternating fashion by reactive gasses. Each half-layer is an ultra-thin film that includes reactive function groups on the surface such that a successive half-layer deposited will react with these available functional groups while leaving new function groups to react with a next half-layer deposited. In this manner, half reactions can generate half-layers such as, for example, silicon interspaced with half-layers of nitride, oxide, or oxynitride that combined, will build up into films of SiN, SiO₂, or SiON.

The films can be applied within the process chamber using a cycling layer deposition (CLD) method or an atomic layer deposition (ALD) method that alternately deposits the half-layers of silicon with the half-layers of nitride, oxide, or oxynitride until total film thickness requirements are met. Using either process, CLD or ALD, low surface roughness, and negligible pattern loading due to the cyclic deposition of ultra-thin layers can result. CLD can provide low impurities within the deposited film and increased wafer throughput rates because of higher process temperatures but where deposition of the silicon layer may not be self-limiting. As a result, the non self-limiting half-layer deposited can be more than a single molecule in thickness. ALD of silicon-based films can provide layer depositions that are completely self-limiting (i.e. both half-layers can be monomolecular in thickness) but with higher film impurities and lower wafer throughput rates relative to CLD when using comparable reactive chemistry. Using the CLD method or the ALD method, the alternating ultra-thin half-layers can be deposited onto a silicon or silicon dioxide surface of a wafer by alternately flowing two or more reactive gasses. For any film deposited, the two or more gasses can be converted to a plasma prior to contacting the wafer.

When depositing a Si-based film a first reactive gas can be a nitrogen (N) source gas (to contribute N to a nitride half-layer), an oxygen (O) source gas (to contribute O to an oxide half-layer), or a combination of nitrogen and oxygen (O/N) source gasses (to contribute O/N an oxynitride half-layer), while a second reactive gas can be a silicon source gas (to contribute Si to a Si-containing half-layer).

Cycling layer deposition (CLD) occurs at wafer temperatures that are high enough to remove impurities such as hydrogen and chlorine from the deposited film. In removing these impurities, CLD may use process temperatures in the range of approximately 300-750° C. depending on the film deposited. A result of CLD deposition is that one of the half-layers may not be self-limiting, i.e. film growth will not stop as a monomolecular layer. For Si-based films, CLD deposition can be in the temperature range of approximately 450-600° C. and where the silicon half-layer may not be self-limiting while deposition of the oxide half-layer, the nitride half-layer, or the oxynitride half-layer are self-limiting at most process temperatures. Self-limiting half-layers will grow two dimensionally (2D) on a surface until the surface is completely covered and then growth will stop which means that half-layer thickness will not increase further from what has been deposited to complete the 2D coverage. Non self-limiting half-layers will continue to grow in thickness by the half reaction as long as the process conditions for such growth are present. Since the reaction temperature is set to reduce impurities in the film, maintaining a silicon half-layer thickness deposited to the scale of angstroms requires control of other process conditions such as, for example, wafer exposure time, chamber pressure, and reactive gas flow rate.

For both CLD and ALD methods, a single cycle for film deposition, generated by half reactions depositing two ultra-thin half-layers, can be repeated to form films. Such single cycles can be, for example, to form SiN where the nitrogen (N) source gas can flow over a silicon surface to be followed by a flow of the silicon source gas. One cycle to form a film of SiO₂, can require an oxygen (O) source gas to flow over the silicon surface to be followed by the silicon source gas flow. One cycle to form a film of SiON can use a source gas that is a ratio of N source gas and O source gas (O/N) to flow over the silicon surface. After the ratio of N to O source gasses have flowed, a flow of the silicon source gas can be performed. In practice, the O/N ratio can be from zero to one, meaning the flow can be all N source gas, all O source gas, or any ratio in between to selectively form films of SiN, SiO₂, and/or SiON. The O/N ratio can be changed and/or varied throughout processing depending on process conditions and the silicon, N, and O source gas chemistries and the required stoichiometry for each half reaction. When depositing Si-based films such as SiN, SiO₂, and/or SiON by CLD, the process temperature (reaction temperature) for depositing the Si half-layer can be set in the range of approximately 450-600° C. with approximately 500° C. preferred. Depositing the O, N, and/or ON half layer can be the same as the Si half-layer or can be different since the half reaction for the O, N, and/or ON half-layer is self-limiting at most process temperatures.

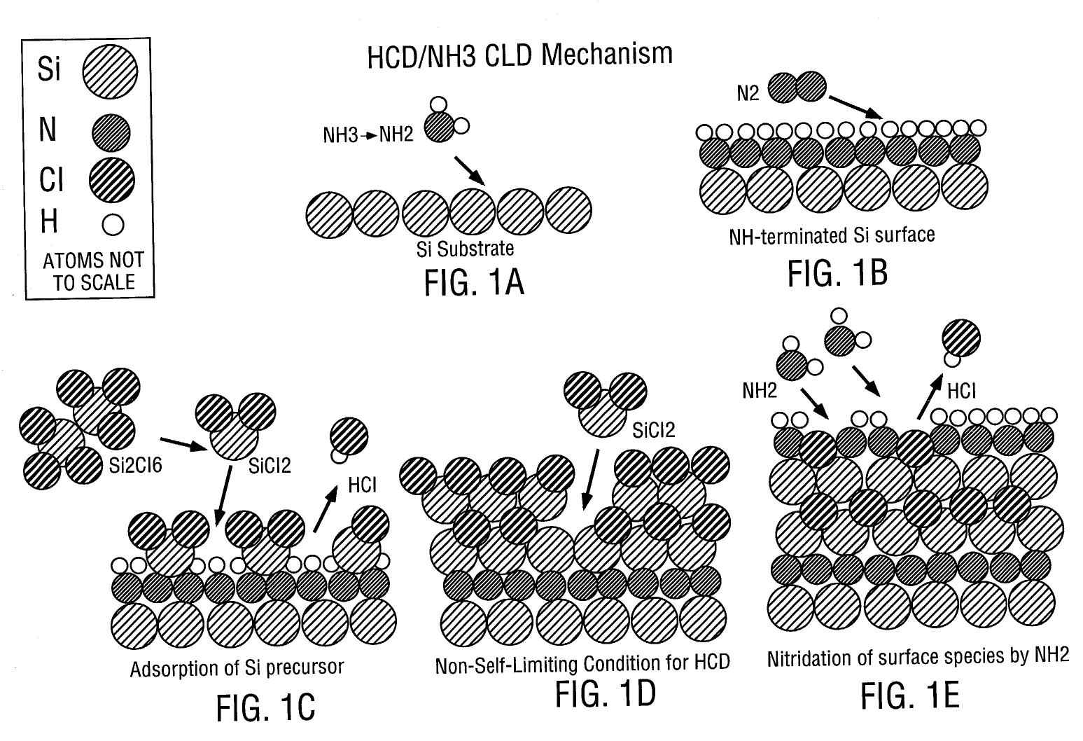

In one embodiment, a deposition of SiN with reactive gasses ammonia and HCD is selected to illustrate the CLD process method. FIGS. 1A-1D are illustrations of the surface of the wafer at stages in the SiN deposition. Prior to a first cycle to deposit a coating of SiN, an existing silicon dioxide layer may have to be removed to expose the underlying bare silicon. To remove the oxide layer, the wafer can be dipped in a solution of hydrofluoric acid (HF), which can leave the exposed silicon surface as a variety of hydrogen terminated species. The next step can flow an inert gas through the process chamber to remove any atmosphere. FIG. 1A is an illustration of the first step in SiN deposition where an ammonia gas is first converted to NH₂ by transitioning to a plasma. The NH₂ can flow over the exposed bare silicon surface where the silicon surface has been heated to approximately 500° C. FIG. 1B is an illustration of NH₂ attached to Si forming an ultra-thin Si—NH coating (—NH from the NH₂ attaches to the pre-existing Si- surface). The Si—NH deposition forms two dimensionally to be self-limiting where the nitridation step coats the surface with a layer that is on the atomic level until the entire surface is covered and after which the deposition automatically stops, i.e. Si—NH will not build upon itself to increase the nitridation coating thickness.

A pump and/or purge operation can be performed before and after each flow step. The pump step can involve placing a vacuum or partial vacuum within the process chamber to remove gasses and impurities generated by a previous reactive gas flow step. The purge operation can flow an inert gas such as, for example, argon (Ar) or nitrogen (N₂) gas through the process chamber to remove residual or remaining reactive gasses, reactive gas products, atmosphere, and escaping film impurities. During the pump and/or purge operations the wafer can remain at approximately 500° C.

FIG. 1C is an illustration of the second reactive gas flow step where HCD gas (hexachlorodisilane, chemically represented as Si₂Cl₆), a silicon source gas, can be transitioned to SiCl₂ molecules through the transition to a plasma. SiCl₂ can then flow onto the previously nitrided silicon surface, heated to approximately 500° C., where the Si is deposited as N—SiCl film. As a result of the approximately 500° C. wafer temperature, H and Cl can be removed as gasses. Depositing the Si film (as N—SiCl), as shown in FIG. 1D, may not be self-limiting since the HCD gas is reacting at approximately 500° C. and as a result, a thickness of more than one molecular layer of Si film (—SiCl) can be deposited (two layers of —SiCl shown). Depositing the —SiCl layer to a required thickness can be accomplished through control of other process conditions such as, for example, chamber pressure, degree of ionization, wafer exposure time, and silicon source gas flow rate through the process chamber. FIG. 1E is an illustration of the next nitridation step by NH₂, over the previously deposited Si-containing layer (N—SiCl) at a wafer temperature of approximately 500° C., where the thickness of the Si-containing layer can be more than one molecule thick, i.e. not an atomic layer. The approximately 500° C. wafer temperature continues to remove H and Cl impurities as gasses carried out by flow of the reactive gas and the later pump and/or purge operations.

This method of one embodiment for SiN deposition is accomplished with an alternating flow of the two reactive gasses under careful process controls. The flow of ammonia can first be applied onto the wafer surface and then stopped, where the wafer surface can be pre-heated to approximately 500° C. Residual ammonia and N-containing reactive species in the process chamber can be removed by pump and purge. A flow of HCD can then be applied to the wafer still heated to approximately 500° C. and the flow then stopped. The flow of HCD and ammonia reactive gasses can be continued to alternately apply each half layer until a final film thickness is achieved. Each flow step can be followed by a pump only, a purge only or a pump step coupled with a purge with the wafer temperature maintained at approximately 500° C. throughout the process. The pump and/or purge assure that HCD and NH₃ do not coexist in the process chamber simultaneously. Should HCD and NH₃ coexist, ammonium chloride (NH₄CIl) could form as a particulate and lower device yield overall.

The CLD method for SiN film deposition repeats the cycle of nitridation of Si as Si—NH, followed with the deposition of Si as N—SiCl having surface reactions that can provide the buildup of SiN layers. Due to the approximate 500° C. process temperatures, impurities that are by-products of the reaction, such as hydrogen and chlorine, can be effectively removed from the deposited film as gasses

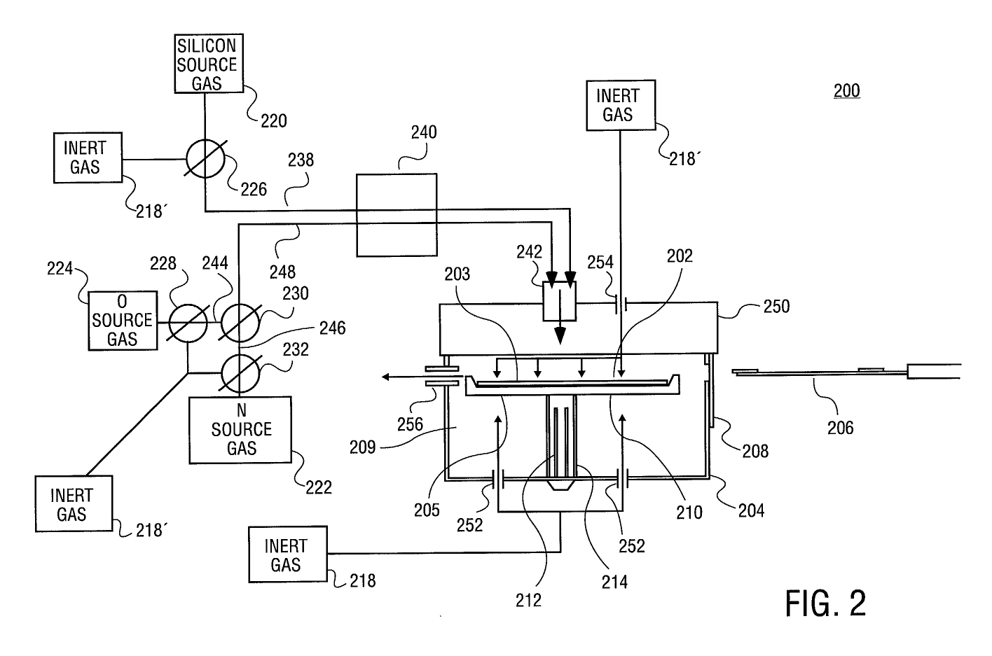

FIG. 2 is an illustration of one embodiment of the cold wall single wafer process chamber for silicon based film deposition. The wafer 202 can be positioned within the cold wall single wafer process chamber 204 (process chamber) by a robot arm 206. A side gate 208 can allow access to the interior 209 of the process chamber 204 where the wafer 202 can be placed onto a wafer holding bracket 210 such as a susceptor. The susceptor 210 can be heated by resistive heating coils (not shown) buried within the susceptor 210 and/or with resistive heating rods 212 placed within a support tube 214 of the susceptor 210.

The process chamber 204 can have an interior volume 209 of approximately 16 liters to handle wafer sizes up to 300 mm in diameter, however, the entire process chamber (including gas apparatus) 200 and the disclosed method can be scaled to incorporate wafers larger than 300 mm. A variety of inert process gasses 218 and 218′ and reactive gasses, 220, 222, and 224 can be directed into the process chamber 204 through a set of valves 226, 228, 230, and 232. Inert gases 218 and 218′ may also be injected into the process chamber 204 at other locations 252 and 254. Reactive gasses, that alternately apply a half-layer, can be a silicon source gas 220, such as, for example HCD, or a N source gas 222, such as, for example, ammonia, and/or an O source gas 224, such as oxygen (O₂). The reactive gasses 220, 222, and 224 can first be dissociated to a plasma by a remote plasma unit 240 prior to entering the process chamber 204. Plasma formation generates a percentage of the silicon, N and/or O source gasses into dissociated ions. The plasma aids in silicon, N, and/or O adsorption onto the film surface. The plasma can be generated such as, for example, through the use of a remote plasma unit 240 using RF energy where the flow of the plasma is then directed into the cold wall single wafer process chamber 204. Alternate methods of gas dissociation and adsorption of silicon, oxygen and/or nitrogen onto the film surface can be achieved by such methods as with radiant heat, UV light, or from the assistance of any combination thereof.

The inert gasses 218 and 218′ that can be used to purge the process chamber 204 of atmosphere, or of residual reactive gasses 220 222, and 224, or of residual reaction products coating the process chamber interior, can be, for example, argon or nitrogen. The inert gasses 218 and 218′ can be used before and/or after flow of each reactive gas 220, 222, and 224.

In one embodiment, valves can connect gas lines between different gasses. Silicon source gas 220 can be connected to the inert gas 218′ by a valve 226 such that a valve setting can flow only silicon source gas 220, or only flow the inert gas 218′ or flow any volumetric ratio of the two gasses along a gas line 238. A flow of the ratio of silicon source gas 220 diluted by inert gas 218′ can allow the inert gas 218′ to act as a carrier. A gas output from the valve 226 can pass along the gas line 238, through the plasma generator 240, and into the process chamber 204 at fitting 242.

In one embodiment, the O source gas 224 and the inert gas 218 can be connected to a valve 228 such that a valve setting can flow only the O source gas 224, or flow only the inert gas 218′, or flow any volumetric ratio of the two gasses 224 and 218′ into gas flow line 244. The N source gas 222 and the inert gas 218′ can be connected to valve 232 such that a valve setting can flow only the N source gas 222, or flow only the inert gas 218, or flow any volumetric ratio of the two gasses 222 and 218′ into gas flow line 246.

A valve 230 can be connected to gas flow line 244 and 246 such that a valve setting can flow only the gas from flow line 244, or only the gas from flow line 246, or any volumetric ratio of gasses from the two flow lines 244 and 246. The output from the valve 230 can flow into gas line 248, pass through the plasma generator 240 and into the process chamber 204 at fitting 242 positioned in a process chamber lid 250.

A flow of the inert gas 218 at ambient temperature can be directed onto the bottom 205 surface of the susceptor 210 to restrict the deposition of products from the chemical reactions onto the susceptor 210. The flow of the inert gas 218 can also be used to aid in the purge process. This inert gas 218 can flow through one or more fittings 252 located at a floor of the process chamber 204. A second flow of the inert gas 218 can be positioned to enter the process chamber at fitting 254 and flow onto the top surface 203 of the wafer to aid in temperature distribution along the wafer from heat conducted from the susceptor 210 and to aid in the purge process.

Any of the gasses 218, 218′, 220, 222, and 224 placed within the process chamber 204 can exit the process chamber 204 through an exhaust vent port 256. In one embodiment, the exhaust vent port 256 can be sized to provide a throat (the smallest cross-section to gas flow) that can set a gas flow rate through the process chamber 204 and a chamber pressure.

With all gasses turned off, the exhaust vent port 256 can be switched to draw a full or partial vacuum (pump step) on the process chamber interior 209 to remove residual process gasses 220, 222, 224, or atmosphere. The exhaust vent port 256 and gas valves 226, 228, 232, and 230 can then be switched to allow a flow of an inert gas (purge step) 218 as well as the inert gasses 218 and 218′ through fittings 252 and 254 to further purge or remove residual reactive gasses 220, 222, and/or 224. In alternate embodiments, the vacuum step (pump) or the vent step (purge) can each be used alone, or the purge step can be used in combination with the pump step.

The cold wall single wafer process chamber 204 can be cooled through normal heat conduction through the process chamber walls and convection from the outer surfaces of the chamber or chamber cooling can be actively aided with liquid cooling through channels within the chamber walls (not shown) such as with water.

The reactive gasses may flow into the process chamber at ambient temperatures or may be pre-heated to ensure that the reactive gasses enter the process chamber as a vapor and not as a liquid. Reactive chemistry such as some of the halogenated Si source gasses as well as ammonia may have to be heated to temperatures in the range of approximately 180-200° C. to guarantee they will be purged and will not remain to mix and form NH₄CI particles in the process lines and/or the process chamber.

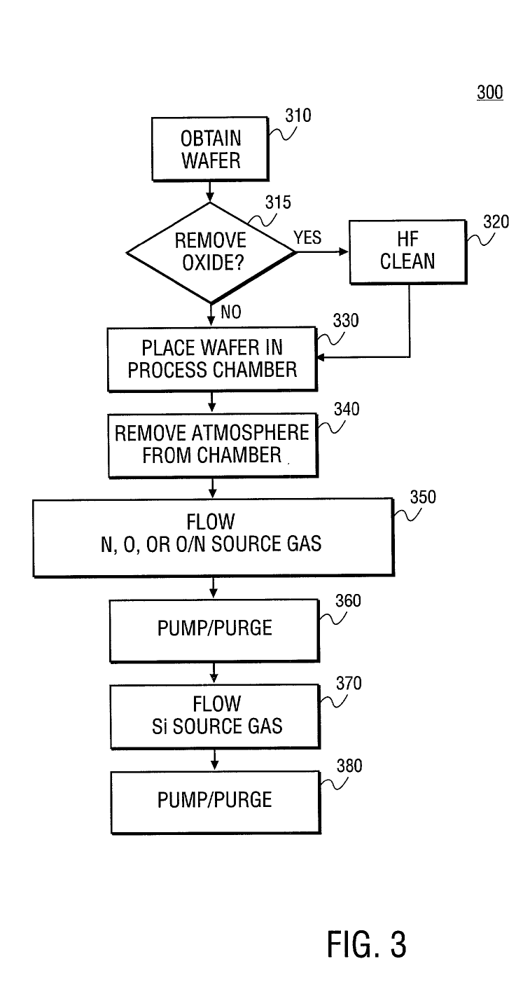

FIG. 3 is an illustration of a flow diagram of one embodiment of a method for CLD or ALD deposition of a film of SiN, SiO₂, or SiON. The first step 310 for a single cycle in the deposition process 300 can begin by obtaining a wafer that has a native oxide (SiO₂) surface coating. If the oxide is to be removed 315, the next step 320 places the wafer into an HF solution to strip off the oxide from the wafer surface exposing the underlying bare silicon. After HF removal of the oxide, the wafer can be bathed in a neutral or slightly acidic solution to remove any remaining HF. In step 330, after removal of the silicon oxide, the wafer can be placed in the process chamber. In step 340, once the wafer is in the chamber there can be a vacuum applied followed with a purge of an inert gas to remove the atmosphere from the chamber interior. After the atmosphere has been removed, the chamber is filled with a flow of a N source gas, and/or an O source gas to form a N-, O-, or O/N-containing half layer on a silicon surface, step 350. In step 360, the source gas is turned off and the chamber is evacuated with a vacuum followed by a purge. Next, in step 370, the chamber is filled with a flow of a silicon source gas to attach Si to the N-, O-, or O/N-containing half-layer. In step 380, the process chamber is again evacuated with a vacuum followed with an inert gas purge

Referring again to FIG. 2, one embodiment of a method to deposit SiN by CLD is described. After the HF cleaning process, the wafer 202 can be transferred into the susceptor 210 of the cold wall single wafer chamber 204 where the susceptor 210 can heat the wafer 202 to approximately 500° C. Any remaining atmosphere within the process chamber 204 can be pumped with an approximate 10 milli-Torr (mTorr) partial vacuum applied for approximately 7 seconds. The partial vacuum can be followed by a purge of argon gas 218 and 218′ flowing through the process chamber 204 for approximately 7 seconds. Next, the flow of ammonia gas 222 can be dissociated into a plasma 240 prior to entering the process chamber 204. The flow of ammonia gas 222 over the wafer 202 can occur for approximately 2 seconds at a process chamber 204 pressure of approximately 25 Torr, a gas flow rate of approximately 4000 sccm (standard cubic centimeters per minute), while maintaining the wafer temperature at approximately 500° C. Following the ammonia step, a pump step can occur with a partial vacuum of approximately 10 mTorr (milli-Torr) applied to the process chamber 204 for approximately 5 seconds followed by a purge of argon gas 218 and/or 218′ applied for approximately 5 seconds. The purge can be accomplished by venting the purge gasses 218 and/or 218′ out the exhaust vent port 235. The purge can occur at a flow rate of approximately 4000 sccm onto the top side 203 of the wafer 202, and a flow rate of approximately 2000 sccm directed onto the bottom side 205 of the susceptor 210 with the wafer 202 temperature remaining at approximately 500° C. Next, a flow of HCD gas 220 can be initiated that can last for approximately 2 seconds at a pressure of approximately 20 Torr and a flow rate of approximately 340 sccm with argon carrier gas. Finally, the cycle for deposition of one SiN layer is completed when the remainder of the last reactive gas 222 is removed with the pump and inert gas purge of the process chamber 204 as described above.

In one embodiment, a SiN coating (not shown) totaling approximately 50 Å is deposited onto the wafer 102, where each cycle; a flow of ammonia followed with a flow of HCD, can deposit approximately 3.3 Å of SiN in a process that takes approximately 10-30 seconds per cycle. This SiN deposition process can achieve approximately 10 wafers per hour per chamber for the deposition of the 50 Å film thickness. Films of up to 100 Å thick can be deposited onto a silicon substrate to coat, for example, silicon nitride/SiO₂ stacked gate dielectrics which can efficiently reduce diffusion of unwanted chemistry such as boron from the p+-polycrystalline-Si gate.

In alternate embodiments for SiN deposition by CLD, different reactive gasses may be chosen to construct the SiN coating. In alternate embodiments, silane (SiH₄) or disilane (Si₂H₆), halogenated precursors such as: DCS (SiH₂Cl₂ or dichlorosilane), SiCl₄, or Sil₄, or metallorganic precursors such as: BTBAS (bis[tertiary-butylamino]silane), TEOS (tetraethoxysilane), and silicon methyl amino compounds may be used for the silicon source. A compound such as hydrazine (N₂H₂) can be an alternate nitrogen source for the nitride. Using these alternate embodiment reactive gasses can still use the same approximate parameters as described for SiN deposition with ammonia and HCD.

In another alternate embodiment for SiN deposition, the ALD process can be used which can have approximately similar process parameters for times, pressures, flow rates and wafer temperature, as with the CLD process methods with the exception that the process occurs at a wafer process temperature low enough to deposit the Si-containing half-layer in the self-limiting regime. Since ALD can have both half-reactions deposited by the self-limiting mechanism, some chemistry appropriate for CLD may not be effective by ALD, such as silane and disilane. The ALD wafer temperature range can be below approximately 500° C. and more specifically below approximately 400° C.

In one embodiment for SiO₂ film deposition, the CLD process can be used. In an alternate embodiment for SiO₂ film deposition, the ALD process can be used. Either the CLD or the ALD processes, when depositing SiO₂ film, can have approximately similar process parameters for exposure times, pressures, flow rates, wafer temperature, etc., as with the ALD and CLD process methods described above for SiN deposition. Reactive gas chemistry can include for the O source gas a selection from; oxygen (O₂), nitrous oxide (N₂O), ozone (O₃) and H₂O. Reactive gas chemistry for the Si source gas can include a selection from the same reactive gas chemistry as described for SiN film formation above.

In one embodiment for SiON film deposition, the CLD process can be used. In an alternate embodiment for SiON film deposition, the ALD process can be used. Either the CLD or the ALD processes, when depositing SiON film, can have the approximately similar process parameters for exposure times, pressures, flow rates, wafer temperature, etc., as with the ALD and CLD process methods described above for SiN deposition. SiON film deposition can occur through alternating layers of silicon- and O/N-containing half-layers where the O/N-containing half-layer is provided by flowing simultaneously the N source gas and the O source gas at a predetermined flow ratio. Reactive gas chemistry for the silicon source gas, the O source gas, and the N source gas can include a selection from the same reactive gas chemistry as described above for the SiN and SiO₂ film depositions.

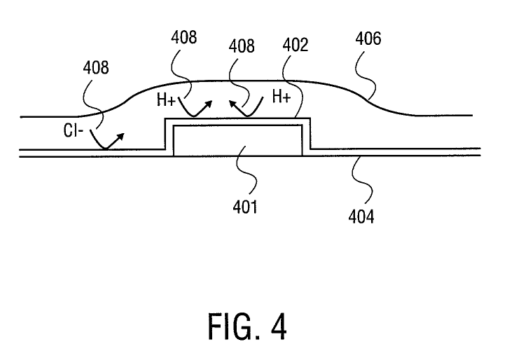

FIG. 4 is an illustration of one embodiment of a barrier seed layer of SiN deposited by CLD or ALD, followed by a second layer of SiN deposited by CVD. As shown in FIG. 4 (not to scale), a thin layer of SiN 402 can be deposited by CLD or ALD over a gate electrode 401 on a wafer surface 404 where the SiN barrier seed layer 402 totals in the approximate range of 20-150 Å thick. This SiN barrier seed layer 402 deposited by CLD or ALD can act as a barrier to impurities 408 from a later coating of an SiN layer deposited by CVD 406 and other subsequent layers. The CLD/ALD barrier seed layer 402 can take advantage of its low hydrogen concentration (i.e. less than 4% [H]) and at the same time act as a barrier to hydrogen and chlorine 408 that may otherwise later penetrate the wafer 404 from the CVD SiN layer (7-15% [H]) 406.

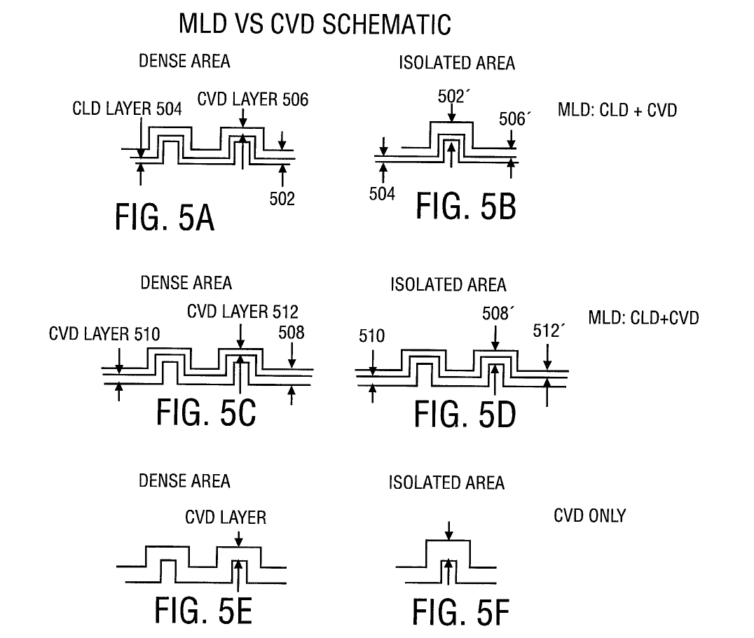

FIGS. 5A-5D are illustrations of a CVD layer deposition verses a mixed layer deposition (MLD) method. MLD allows the deposition of a film to be tailored by using both the CLD or ALD and the CVD deposition methods. First, the degree or magnitude of pattern loading that can be allowed on a wafer must be determined. Next, a first layer of film (SiN, SiO₂, or SiON) is deposited by CLD or ALD to a thickness with little or no pattern loading. Finally, a second thickness is deposited of SiN, SiO₂, or SiON by CVD to reach the total thickness required where some pattern loading effects will be realized depending on the thickness applied by CVD. MLD allows for the tailoring of pattern loading and cycle time to be optimized on a “sliding scale” where the scale on the pure CLD or ALD end is no pattern loading and slower cycle times and at the pure CVD end with faster cycle times and pattern loading problems. The CLD or ALD film could be deposited first to provide a barrier layer to impurities in later deposited films and to provide a “no pattern loading” surface to start later CVD deposition. Beyond providing a barrier seed layer, the CLD or ALD thickness could be increased as needed (along the sliding scale) such that completion of the total film thickness by CVD would provide a pattern loading condition that is acceptable for a particular wafer design while still gaining some benefit of the faster cycle times of CVD.

FIGS. 5A-5D are illustrations of embodiments of pattern loading effects when depositing SiN. In one embodiment, as shown in FIGS. 5A and 5B, SiN is deposited having a total thickness that is a combination of two layers, a first layer of SiN deposited by CLD 504 that is approximately 30 Å thick and a second layer of SiN deposited by CVD 506 that is approximately 345 Å thick. FIG. 5A is an illustration of the CLD+CVD deposition thickness 502 where the layers 504 and 506 are deposited in a dense device (pattern) area of a wafer. Total film deposition 502 in this dense device area is approximately 330 Å when measured at the base. FIG. 5B is an illustration of the CLD and CVD deposition thicknesses 504 and 506′ where the layers are deposited in an isolated device area of the wafer. Total film deposition 502′ in this isolated device area is 375 Å when measured at the top of a device. As a result, FIGS. 5A and 5B show (not to scale) that deposition by CLD and CVD has a pattern loading effect of approximately 12%. FIGS. 5C and 5D are illustrations of another embodiment of a CLD coating and a CVD coating applied to both dense and isolated areas. FIGS. 5C and 5D illustrate a deposition of SiN by CLD that is approximately 100 Å thick and a deposition by CVD of SiN that is 250 Å thick. FIG. 5C is an illustration of the CLD layer 510 and the CVD layer 512 deposited in the dense device (pattern) area of the wafer. Total film deposition 508 in this dense device area, when measured at the base, is approximately 320 Å. FIG. 5D is an illustration of the CLD layer thickness 510 and the CVD layer thickness 512′ where the layers are deposited in an isolated device area of the wafer. Total film deposition 508′ in this isolated device area is 330 Å when measured at the top of a device. As a result, FIGS. 5C and 5D show (not to scale) that deposition by CLD and CVD has a pattern loading effect of approximately 9%. FIGS. 5E and 5F show for comparison that film deposited by CLD only can provide an approximate 13% pattern loading effect.

Acceptable pattern loading limits might be determined on a case-by-case basis and the ratio of coating thickness from CLD vs. CVD to meet these pattern loading limits could either be calculated or determined by testing. Pattern loading free SiN by cycling layer deposition (CLD) not only reduces overall pattern loading from CVD but also helps CVD SiN grow evenly.

By way of a few examples, the method can be described for a generalized understanding but in no way is the method restricted to the stated film chemistry, limitations or results. In one example (FIGS. 5A and 5B), a thin layer of SiN 504 is deposited over a wafer by CLD with the remainder of the SiN deposited by CVD 506 and 506′ that could provide a possible wafer process rate of approximately 25 wafers per hour (wph) per chamber and having noticeable pattern loading. In a second example (FIGS. 5C and 5D) the thickness of SiN deposited by CLD 510 could be the same as deposited by CVD 512 and 512′ for a possible wafer process rate of approximately 15 wph. Using MLD, the coating thickness applied by each method, CLD vs. CVD, could be varied to meet specific requirements for total coating thickness, pattern loading, and wafer throughput while avoiding or minimizing problems associated with impurities.

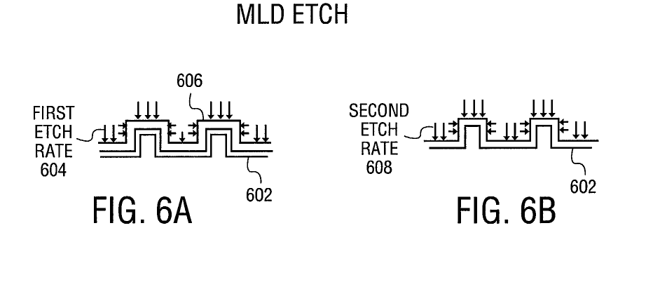

Using the same material in the films deposited, mixed layer deposition can be used to determine an end of a chemical etch operation on a film. Factors which can effect a rate of etch can be the density of the film being etched and the amount of impurities within the film. When the same film material is deposited by ALD, CLD, and CVD, etch rates for films deposited by ALD or CLD can be slower than CVD as a result of the higher densities for films deposited by ALD or CLD. The higher density, i.e. lower porosity, from films deposited by ALD or CVD can be a result of the slower deposition rate. FIGS. 6A and 6B illustrate, in one embodiment, for SiN, a density of a film 602 applied by ALD or CVD. The SiN film applied by ALD or CLD can have a density approximately in the range of 2.97-3.00 g/cm³ and provide a first etch rate 604 with etch chemistry. The SiN film applied CVD 606 can be deposited in the density range of approximately 2.85-2.96 g/cm³ and provide a second etch rate 608 with the same etch chemistry.

The density of the film deposited can be compared to a theoretical density for the film material. The theoretical density would be a maximum density possible for the film without any impurities or voids. This comparison can be referred to as a relative density where the density of the film deposited is divided by the theoretical density for the film with the ratio multiplied by 100 to give a percent value. The relative density of Si-based films deposited by ALD or CLD can be greater than 85% while Si-based films deposited by CVD can be in the range of approximately 50-85%. When etching Si-based films, high impurities of hydrogen or chlorine can increase the etch rate. Impurities, such as, for example, hydrogen and/or chlorine in Si-based films deposited by CLD can be less than 5 atom percent and greater than 15 atom percent for Si-based films deposited by CVD where atom percent is the number of atoms of impurity in 100 atoms of film deposited with the ratio multiplied by 100. By evaluating the etch solution chemistry, either by rate of consumption of the etchant or rate of increase of etch products such as SiF₄, a change in the etch rate, i.e. a transition such as, for example, from CVD SiN to CLD/ALD SiN, can be determined as an end point to stop the etch process.

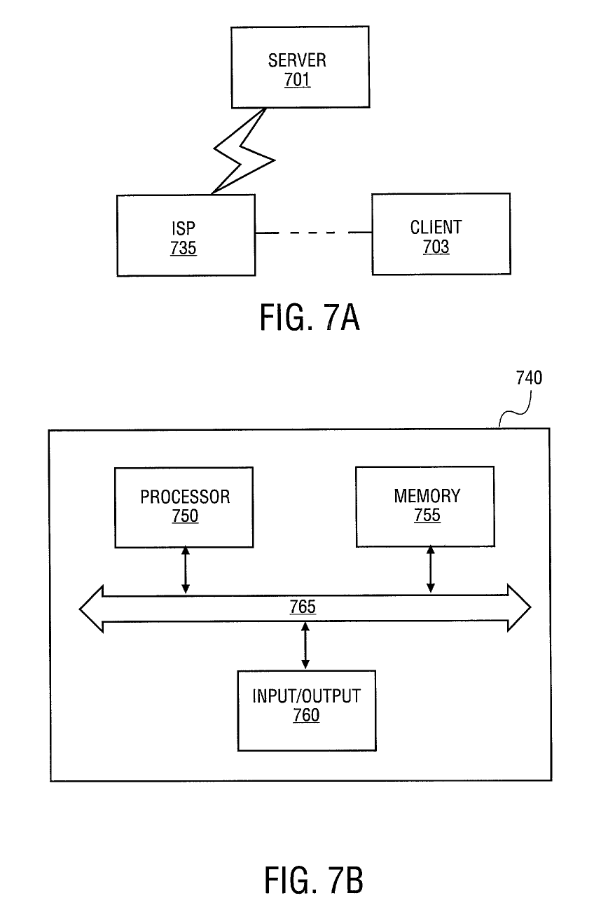

FIGS. 7A & 7B illustrate one embodiment of a machine such as a computer. The machine 740 may be suitable for implementation of a client 703 through an ISP provider 735, a server 701, or both. Machine 740 includes processor 750, memory 755, input/output 760 and bus 765. Bus 765 is coupled to each of processor 750, memory 755 and input/output 760, allowing communication and control there between.

In the foregoing, the present invention has been described with reference to specific exemplary embodiments thereof. It will, however, be evident that various modifications and changes may be made thereto without departing from the broader spirit and scope of the present invention. In particular, the separate blocks of the various block diagrams represent functional blocks of methods or apparatuses and are not necessarily indicative of physical or logical separations or of an order of operation inherent in the spirit and scope of the present invention. The present specification and figures are accordingly to be regarded as illustrative rather than restrictive.

What is claimed is

1. A method for film deposition, comprising:
flowing a first reactive gas over a top surface of a wafer in a cold wall single wafer process chamber to form a first half-layer of the film on the wafer;
stopping the flow of the first reactive gas;
removing residual first reactive gas from the cold wall single wafer process chamber;
flowing a second reactive gas over the first half-layer to form a second half-layer of the film where deposition of the second half-layer is non self-limiting;
controlling a thickness of the second half-layer by regulating process parameters within the cold wall single wafer process chamber;
stopping the flow of the second reactive gas; and
removing residual second reactive gas from the cold wall single wafer process chamber.

2. The method of claim 1, wherein the first reactive gas may be chosen from the group consisting of N source gas, O source gas, and N/O source gas.

3. The method of claim 1, wherein the second reactive gas is a silicon source gas.

4. The method of claim 1, wherein the film deposited may be chosen from the group consisting of SiN, SiO₂, and SiON.

5. The method of claim 1, wherein the first reactive gas is converted to a plasma prior to contacting the wafer.

6. The method of claim 1, wherein the second reactive gas is converted to a plasma prior to contacting the wafer.

7. The method of claim 1, wherein the first reactive gas is dissociated with UV light.

8. The method of claim 1, wherein the second reactive gas is dissociated with UV light.

9. The method of claim 1, wherein the first reactive gas is dissociated with heat.

10. The method of claim 1, wherein the second reactive gas is dissociated with heat.

11. The method of claim 3, wherein the silicon source gas is selected from the group consisting of HCD, SiCl₄, SiH₂Cl₂, Sil₄, SiH₄, Si₂H₆, BTBAS, TEOS, and silicon methyl compounds.

12. The method of claim 2, wherein the N source gas is selected from the group consisting of ammonia, hydrazine, N₂, and NF₃.

13. The method of claim 2, wherein the O source gas is selected from the group consisting of oxygen, nitrous oxide, ozone, and water.

14. The method of claim 3, wherein the silicon source gas is applied at a pressure range of approximately 1 mT-325 Torr.

15. The method of claim 1, wherein the first reactive gas is applied at a pressure range of approximately 1 mT-325 Torr.

16. The method of claim 3, wherein a flow rate of the silicon source gas through the cold wall single wafer process chamber is approximately 1-1000 sccm.

17. The method of claim 1, wherein the flow rate of the first reactive gas through the cold wall single wafer process chamber is approximately 1-30,000 sccm.

18. The method of claim 1, wherein the cold wall single wafer process chamber has an interior volume of approximately 16 liters or less.

19. The method of claim 1, wherein the wafer temperature is in the range of approximately 300-750° C.

20. The method of claim 4, wherein the wafer temperature is in the range of approximately 450-650° C.

21. The method of claim 4, wherein the wafer temperature is approximately 500° C.

22. The method of claim 1, wherein the first reactive gas is heated to enter the cold wall single wafer process chamber as a vapor.

23. The method of claim 1, wherein the second reactive gas is heated to enter the cold wall single wafer process chamber as a vapor.

24. The method of claim 1, further comprising placing the wafer on a susceptor and flowing an inert gas onto a bottom side of the susceptor.

25. The method of claim 1, wherein removing residual first reactive gas and residual second reactive gas is accomplished with a pump operation.

26. The method of claim 1, wherein removing residual first reactive gas and residual second reactive gas is accomplished with a purge operation.

27. The method of claim 1, wherein removing residual first reactive gas and residual second reactive gas is accomplished with a pump operation and a purge operation.

28. A method for film deposition, comprising:
flowing a first reactive gas to form a first half-layer over a top surface of a wafer in a cold wall single wafer process chamber;
stopping the flow of the first reactive gas;
removing residual first reactive gas from the cold wall single wafer process chamber;
flowing a second reactive gas to form a second half-layer over the first half-layer, where deposition of the second half-layer is non self-limiting;
controlling a thickness from the second half-layer by regulating process parameters within the cold wall single wafer process chamber;
stopping the flow of the second reactive gas;
removing residual second reactive gas from the cold wall single wafer process chamber; and
further depositing the film by CVD.

29. The method of claim 28, wherein the first reactive gas may be chosen from the group consisting of N source gas, O source gas, and N/O source gas.

30. The method of claim 28, wherein the second reactive gas may be a silicon source gas.

31. The method of claim 28, wherein the film deposited may be chosen from the group consisting of SiN, SiO₂, and SiON.

32. The method of claim 30, wherein the silicon source gas is selected from the group consisting of HCD, SiCl₄, SiH₂Cl₂, Sil₄, SiH₄, Si₂H₆, BTBAS, TEOS, and silicon methyl compounds.

33. The method of claim 29, wherein the N source gas is selected from the group consisting of ammonia, hydrazine, N₂, and NF₃.

34. The method of claim 29, wherein the O source gas is selected from the group consisting of oxygen, nitrous oxide, ozone, and water.

35. The method of claim 28, wherein the film deposited includes a barrier seed layer that is 5-150 Å thick.

36. The method of claim 28, wherein the wafer temperature is in the range of approximately 300-750® C.

37. The method of claim 31, wherein the wafer temperature is in the range of approximately 450-650° C.

38. The method of claim 31, wherein the wafer temperature is approximately 500° C.

39. A method for film deposition, comprising:
flowing a first reactive gas over a top surface of a wafer in a cold wall single wafer process chamber to deposit a first half-layer that is self-limiting;
stopping the flow of the first reactive gas;
removing residual first reactive gas from the cold wall single wafer process chamber;
flowing a second reactive gas that over the first half-layer in the cold wall single wafer process chamber to deposit a second half-layer that is self-limiting;
stopping the flow of the second reactive gas; and
removing residual second reactive gas from the cold wall single wafer process chamber.

40. The method of claim 39, wherein the first reactive gas may be chosen from the group consisting of N source gas, O source gas, and N/O source gas.

41. The method of claim 39, wherein the second reactive gas may be a silicon source gas.

42. The method of claim 39, wherein the film deposited may be chosen from the group consisting of SiN, SiO₂, and SiON.

43. The method of claim 41, wherein the silicon source gas is selected from the group consisting of HCD, SiCl₄, SiH₂Cl₂, Sil₄, BTBAS, TEOS, and silicon methyl compounds.

44. The method of claim 40, wherein the N source gas is selected from the group consisting of ammonia, hydrazine, N₂, and NF₃.

45. The method of 40, wherein the O source gas is selected from the group consisting of oxygen, nitrous oxide, ozone, and water.

46. The method of claim 39, wherein the wafer temperature is in the range of approximately 300-750° C.

47. The method of claim 42, wherein the wafer temperature is in the range of approximately 450-650° C.

48. The method of claim 42, wherein the wafer temperature is approximately 500° C.

49. A method for depositing a film onto a wafer, comprising:
depositing a first SiN film having a first density;
depositing a second SiN film having a second density over the first SiN film.

50. The method of claim 49, wherein the first SiN film is deposited by CLD.

51. The method of claim 49, wherein the first SiN film is deposited by ALD.

52. The method of claim 49, wherein the second SiN film is deposited by CVD.

53. A film on a wafer, comprising:
a first Si-based film having a first density;
a second Si-based film having a second density deposited over the first film, where the first Si-based film is the same material as the second Si-based film.

54. The film of claim 53, wherein the first density is higher than the second density.

55. The film of claim 53, wherein the Si-based film deposited may be chosen from the group consisting of SiN, SiO₂, and SiON.

56. The film of claim 53, wherein the Si-based film is SiN.

57. The film of claim 56, wherein, the first density is in the range of approximately 2.97-3.00 g/cm³.

58. The film of claim 56, wherein the second density is in the range of approximately 2.85-2.96 g/cm³.

59. The film of claim 53, wherein the first Si-based film has an impurity concentration of less than 5 atom percent.

60. The film of claim 53, wherein the second Si-based film has an impurity concentration of greater than 5 atom percent.

61. The film of claim 53, wherein the first Si-based film has a relative density greater than 85%.

62. The film of claim 53, wherein the second Si-based film has a relative density in the range of approximately 50-85%.

63. A processing system, comprising:
a processing element,
a memory coupled to the processing element through a bus; and
a Si-based film deposited onto the processing element by CLD.

64. The system of claim 63, wherein the Si-based film is further deposited by MLD.

65. The system of claim 63, wherein the Si-based film deposited may be chosen from the group consisting of SiN, SiO₂, and SiON.

66. The system of claim 63, wherein a Si-based film is deposited onto the memory.
